(19) United States
(12) Patent Application Publication
(10) Pub. No.: US 2015/0338710 A1
(43) Pub. Date: Nov. 26, 2015

(54) ARRAY STRUCTURE, METHOD FOR MANUFACTURING THE SAME AND ARRAY SUBSTRATE

(71) Applicants: BOE TECHNOLOGY GROUP CO., LTD., Beijing (CN); HEFEI BOE OPTOELECTRONICS TECHNOLOGY CO., LTD., Hefei, Anhui (CN)

(72) Inventor: Juncai Ma, Beijing (CN)

(73) Assignees: HEFEI BOE OPTOELECTRONICS TECHNOLOGY CO., LTD., Hefei, Anhui (CN); BOE TECHNOLOGY GROUP CO., LTD., Beijing (CN)

(21) Appl. No.: 14/408,823

(22) PCT Filed: May 30, 2014
(86) PCT No.: PCT/CN2014/078940

§ 371 Date: Dec. 17, 2014

(30) Foreign Application Priority Data
Nov. 15, 2013 (CN) 201310577779.9

(51) Int. Cl. G02F 1/1362; G02F 1/1343; H01L 21/283; G02F 1/1345; H01L 27/12; H01L 21/311

(52) U.S. Cl. CPC G02F 1/136286; H01L 27/124; H01L 27/1259; H01L 21/31111; H01L 21/283; G02F 1/13458; G02F 1/13439; G02F 2001/136254

(57) ABSTRACT

An array structure and a method for manufacturing the same, an array substrate and a display device are provided, the array structure comprises signal input pads (3, 4) and a gate insulating layer (1), wherein the gate insulating layer (1) has grooves (P) in which the signal input pads (3, 4) are located. The grooves (P) function to accommodate the signal input pads (3, 4) for a test such as an array test and a cell test due to a position of the grooves (P) being lower than other layer structures. By means of the groove design, it is possible to decrease a difference of heights of the signal input pads and the display region, increase flatness of the display panel, further improve the uniformity of the aligning, improve the Mura defect caused by the aligning difference due to the height difference during the aligning process, and improve the product properties.

### TECHNICAL FIELD

Embodiments of the present invention relates to an array structure, a method for manufacturing the same, an array substrate and a display device.

### BACKGROUND

Presently, a product line of a thin film transistor (TFT) liquid crystal display mainly includes four processes of array, color filter (CF), cell and module. In the above processes, the array process is intended to form a TFT array on a TFT substrate, mainly including formation of metal layer signal lines and each of pixel capacitance cells on the TFT substrate and obtain the TFT array substrate finally. The CF process mainly includes formation of a black matrix (BM) layer, red, green and blue (RGB) layers (i.e. a color filter layer), a transparent conductive layer and the like on a CF substrate. The cell process is intended to bond the formed TFT and CF substrates together by an adhesive so as to form a complete scaling display panel, mainly including forming an alignment film by printing, aligning of the alignment film, dropping liquid crystal, curing the adhesive and the like. The module process mainly includes assembling the formed display panel with a polarizing filter and a PCB driving circuit attached thereto, with a backlight source so as to form a final display device.

During the cell process, before the TFT array substrate and the CF substrate are bonded, an array test to the TFT array substrate is required, and after the TFT array substrate and the CF substrate are bonded, a cell test is also required. During the array test or the cell test, it is required to provide corresponding signal input pads including an array test signal input pad (AT Pad) and a cell test signal input pad (CT Pad) on the glass substrate. The cell test may be performed after bonding and before cutting, and may be performed after cutting. There is a relative large height difference between a signal input pad region and display region due to the present of the signal input pads, so that the flatness of a surface of the display panel is poor. During performing the following rubbing of the aligning film (that is, formation of the alignment), a difference of the rubbing intensity is generated along a direction of the signal input pads, thereby affecting the formation of the alignment film, occurring Mura phenomenon, so that an obtained liquid crystal screen has a uneven surface lightness.

### SUMMARY

An embodiment of the invention provides an array structure comprising signal input pads and a gate insulating layer, wherein the gate insulating layer has grooves in which the signal input pads are located.

Another embodiment of the invention provides a method for manufacturing an array structure, the method comprising: forming a gate insulating layer on a substrate; and etching a portion of the gate insulating layer corresponding to signal input pads to be formed so as to form grooves in the gate insulating layer.

Another embodiment of the invention provides an array substrate comprising a glass substrate and the above array structure formed on the glass substrate.

Another embodiment of the invention provides a display device comprising the above array substrate.

### BRIEF DESCRIPTION OF THE DRAWINGS

For better understanding technical proposals according to embodiments of the present invention, drawings of the embodiments will be described briefly below. Obviously, drawings in the following description only relate to some embodiments of the present invention, not to limit the present invention.

FIG. 1 is a schematic view showing a connection relationship between signal input pads having various test functions and a display panel at a test stage;

FIG. 2 is a schematic view showing positions for arranging the signal input pads during an aligning process;

FIG. 3 is a cross-sectional view of the signal input pads in FIG. 2 taken along A-A′;

FIG. 4 is a schematic view of an array structure provided in an embodiment of the present invention;

FIG. 5 a flow chart showing steps in a method for manufacturing an array structure provided in an embodiment of the present invention; and

FIG. 6 is a schematic view of an array substrate provided in an embodiment of the present invention.

### DETAILED DESCRIPTION

In order to make the purpose, technology solution and advantages of embodiments of the present invention more clear, technology solutions according to embodiments of the present invention will be described clearly and completely below with respect to drawings of embodiments of the present invention. It is to be understood that the described embodiments are part of but not all of embodiments of the present invention. Based on the described embodiments of the present invention, all other embodiments obtained by those of ordinary skill in the art without any creative labor fall into the protecting scope of the present invention.

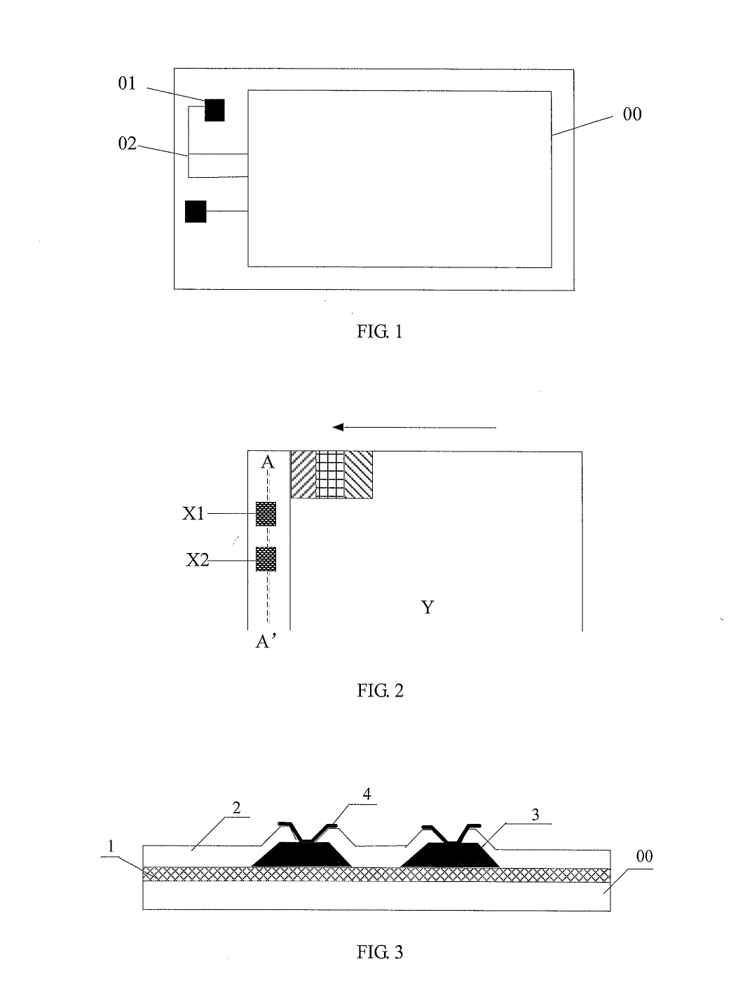

FIG. 1 is a schematic view showing a connection relationship between signal input pads having various test functions and a display panel at a test stage. During processes of performing an array test and a cell test, it is required to arrange corresponding signal input pads at a peripheral of the display panel and connect the signal input pads to corresponding electrode lines in the display panel by a shorting bar. If the cell test is taken as an example, in FIG. 1, “00” denotes a glass substrate, “01” denotes a cell test signal input pad (CT pad), and “02” denotes a shorting bar.

During an aligning process of the above structure, a schematic view of positions for arranging the signal input pads is shown as FIG. 2, in which a direction of an arrow is an align direction. In a display region Y, blue, green and red pixels are provided along the arrow direction. There is a signal input pad region at the peripheral of the display panel, as shown in FIG. 2 by “X”. In FIG. 2, two signal input pads X1 and X2 are shown. The cross-sectional view of the signal input pad region taken along A-A′ is shown as FIG. 3, in which “00” denotes the glass substrate, “1” denotes a gate insulating layer (GI), “2” denotes a passivation layer, “3” denotes a gate electrode, “4” denotes a transparent electrode layer.

It is to be noted that, in the structure shown in FIG. 3, the signal input pads include a first electrode as an electrode pattern (the gate electrode 3 is taken as an example in the present invention) and a second electrode (the transparent electrode layer 4 is taken as an example in the present invention), and the gate electrode 3 is the electrode pattern formed by metal for forming the gate. It would be appreciated that, the above gate electrode 3 is different from a gate electrode of a thin film transistor in the display region, and thus the structure of the signal input pads are not limited thereto. For example, the signal input pads may include an electrode pattern formed by metal for forming source/drain and the transparent electrode layer 4, and they can be configured correspondingly according to patterning processes.

The embodiments of the present invention provide an array structure and a method for manufacturing the same in order to decrease a difference between heights of the signal input pad region and the display region, increase the flatness of the display panel, and improve Mura defect. Furthermore, the embodiments of the present invention also provide an array substrate including the above array structure and a display device including the array substrate.

### A First Embodiment

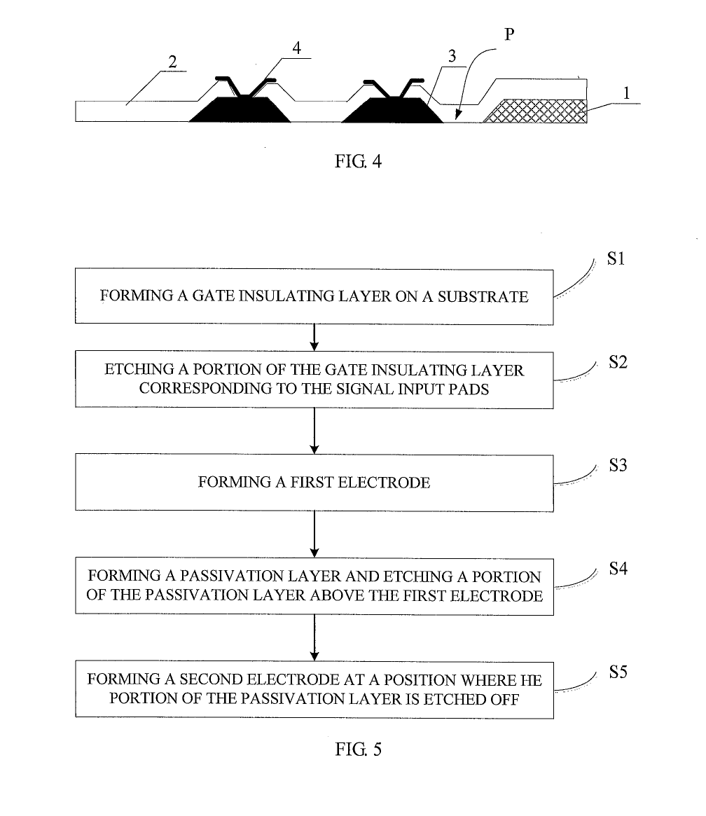

In the first embodiment of the present invention, an array structure is provided. As shown in FIG. 4, the array structure includes a gate electrode 3 and a gate insulting layer 1 having a groove P formed therein, a portion of the gate insulating layer 1 corresponding to the gate electrode 3 is etched off by a patterning process (e.g. including photolithograph, etching and the like).

In the above array structure, grooves for arranging the signal input pads are formed in the gate insulating layer by etching a portion of the gate insulating layer corresponding to the signal input pads (for example, a portion of the gate insulating layer corresponding to the gate electrode). By means of the above groove design, it is possible to decrease a difference of heights of the signal input pads and the display region, increase flatness, and decrease a difference of an aligning level caused by the height difference, so that the occurrence of the Mura phenomenon caused by the aligning difference can be prevented.

The grooves in this embodiment, which function to accommodate the signal input pads for performing test operation, is denoted by P in FIG. 4, and at this time the signal input pads have been formed. When the array substrate and the display panel after bonding are tested, the respective signal input pads are needed, but there is a relatively large height difference between the signal input pad region and the display region after the signal input pads are connected to the array structure, due to the signal input pads having a certain thickness. When the aligning operation is performed by an aligning cloth after the substrate is performed by a coating process, levels of the rubbing by the aligning cloth in different regions (the signal input pad region and the display region) are different due to the height difference, which results in uneven rubbing effect, and in turn results in occurrence of the Mura defect on the resultant array substrate or the display panel so that the display quality is affected. However, in the embodiment, the signal input pads for testing are disposed in the grooves obtained by etching, so that a height of the signal input pad region is relatively close to a height of the display region during performing a test, the height difference caused by the signal input pads is decreased, the uniform rubbing effect is assured, and the Mura phenomenon is prevented.

The signal input pads in the embodiment include array test signal input pads and/or cell test signal input pads. The array test signal input pads (AT Pad) function to perform a test to the array substrate, and the cell test signal input pads (CT Pad) function to perform a test to the display panel, that is, after the signal input pads are connected, a backlight source below the display panel is powered, and defects present on the display panel are inspected by human's eyes or the machinery vision technology. It is to be noted that, the cell test signal input pads are taken as an example in FIG. 4 of the embodiment, in addition to the array test signal input pads and the cell test signal input pads, signal input pads having other test functions may be further included, and may be arranged similarly, the description of which are omitted here.

Furthermore, in the embodiment, the passivation layer 2 is provided on the gate electrode 3, the gate insulating layer 1 and the groove P, a portion of the passivation layer 2 located on the gate electrode 3 is etched off, and the transparent electrode layer 4 is provided on the portion of the passivation layer 2 which is etched off.

As described above, in the array structure provided in the first embodiment of the present invention, the grooves are formed in the gate insulating layer by etching a portion of the gate insulating layer corresponding to the signal input pads (for example, a portion of the gate insulating layer corresponding to the gate electrode) and the signal input pads for testing are displaced in the grooves, so that the difference of the heights of the signal input pad region and the display region can be decreased after the signal input pads are connected, the uniform rubbing effect can be assured, and the Mura phenomenon is prevented.

### A Second Embodiment

The second embodiment of the present invention also provides a method for manufacturing an array structure, the method comprising: etching a portion of a gate insulating layer corresponding to signal input pads (for example, corresponding to gate electrodes) by a patterning process so as to form a groove in the gate insulating layer.

In the embodiment, the grooves function to accommodate the signal input pads for performing a test operation.

Furthermore, in the embodiment, the signal input pads are array test signal input pads and/or cell test signal input pads.

Furthermore, in the embodiment, on the glass substrate, a passivation layer is provided on the gate electrode, the gate insulating layer and the grooves, and a portion of the passivation layer on the gate electrode is etched off.

Furthermore, in the embodiment, a transparent electrode layer is formed at a position where the portion of the passivation layer is etched off.

The method for manufacturing the above array structure includes steps as shown in FIG. 5, and for example, includes the following steps:

Step S1: forming a gate insulating layer 1 on a substrate (e.g. a glass substrate);

Step S2: etching off a portion of the gate insulating layer 1 corresponding to signal input pads by a patterning process;

Step S3: forming a first electrode (for example, a gate electrode 3 in a signal input pad region);

Step S4: forming a passivation layer and etching off a portion of the passivation layer located above the first electrode;

Step S5: forming a second electrode layer (for example, a transparent electrode layer 4) at a position where the portion of the passivation layer is etched off.

It would be appreciated that, the first electrode in the above step S3 may be made of the gate metal. At this time, for purpose of reducing process cost, for example, the method for manufacturing the above array structure may include the following steps:

Step S1′: forming a pattern including a gate in a display region and a gate electrode 3 in a signal input pad region on a substrate (e.g. a glass substrate);

Step S2′: forming a gate insulating layer 1 and etching off a portion of the gate insulating layer 1 corresponding to signal input pads by a patterning processes;

Step S3′: forming a passivation layer 2 and etching off a portion of the passivation layer 2 located above the gate electrode 3;

Step S4′: forming a transparent electrode layer 4 at a position where the portion of the passivation layer 2 is etched off.

It is to be noted that, after performing the step S2′, the pattern of the first electrode have been exposed, and in this case, the effects of the present invention can be achieved with reducing the process cost, that is, the height difference between the signal input pad region and the display region may be reduced and thus the aligning uniformity can be improved.

Those skilled in the art can understand the above first electrode may also be made by source/drain metal material, as long as the patterning process is adjusted correspondingly, the detailed description of which is omitted here.

As described above, in the method for manufacturing the array structure provided in the embodiment, the signal input pads for testing are provided into the grooves formed in the gate insulating layer, so that the height difference between the signal input pad region and the display region is reduced effectively, the uniform rubbing effect is assured, and the occurrence of the Mura phenomenon is further prevented.

### A Third Embodiment

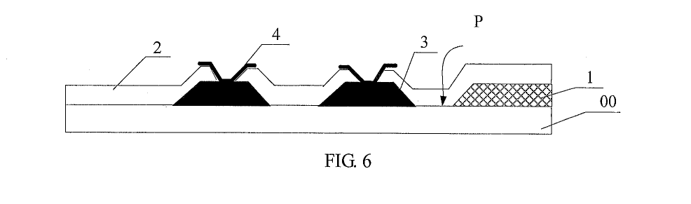

The third embodiment of the present invention also provides an array substrate, as shown in FIG. 6, with the array structure in the above first embodiment formed on the glass substrate.

Furthermore, embodiments of the present invention also provide a display device comprising the above array substrate. In the above display device, since a portion of the gate insulating layer corresponding to the signal input pads (for example, a portion of the gate insulating layer located below the gate electrodes) is etched off so as to form grooves in the gate insulating layer, and the signal input pads for testing are provided in the grooves, the difference of heights of the signal input pad region and the display region can be decreased after the signal input pads are connected, and the uniform rubbing effect can be assured. By means of the above display device, since the uniform aligning is performed on a surface of the display panel, the Mura phenomenon can be prevented and the good display effect of the display device can be assured.

The above embodiments are only for the purpose of describing technical proposal of the present invention rather than limiting it. While the present invention has been described in detail with reference to the above-mentioned embodiments, those of ordinary skill in the art should understand that they can modify the technical solution recorded in the above embodiments or conduct equivalent substitution for a part of technical features thereof and these modifications or substitutions will not make the nature of respective technical solution to depart from the spirit and scope of technical solutions of embodiments of the present invention.

This application claims the priority benefit of Chinese Patent Application No. 201310577779.9 filed on Nov. 15, 2013, the disclosure of which is incorporated herein as a part of the application in its entirety by reference.

1: An array structure comprising signal input pads and a gate insulating layer, wherein the gate insulating layer has grooves in which the signal input pads are located.

2: The array structure of claim 1, wherein the signal input pads comprise a first electrode formed in the groove.

3: The array structure of claim 2, wherein the signal input pads include an array test signal input pad and/or a cell test signal input pad.

4: The array structure of claim 2, wherein a passivation layer is provided on the first electrode, the gate insulating layer and the grooves, and a portion of the passivation layer located above the first electrode is etched off.

5: The array structure of claim 4, wherein a second electrode is provided at a position where the portion of the passivation layer is etched off.

6: The array structure of claim 5, wherein the first electrode is made of metal material and the second electrode is made of transparent electrode material.

7: A method for manufacturing an array structure, the method comprising:
forming a gate insulating layer on a substrate; and
etching a portion of the gate insulating layer corresponding to signal input pads, so as to form grooves in the gate insulating layer.

8: The method for manufacturing the array structure of claim 7, wherein the grooves function to accommodate the signal input pads for performing a test operation.

9: The method for manufacturing the array structure of claim 7, wherein the signal input pads are an array test signal input pad and/or a cell test signal input pad.

10: The method for manufacturing the array structure of claim 7, wherein the signal input pads comprises a first electrode formed in the groove.

11: The method for manufacturing the array structure of claim 10, wherein a passivation layer is provided on the first electrode, the gate insulating layer and the groove, and a portion of the passivation layer located above the first electrode is etched off.

12: The method for manufacturing the array structure of claim 11, wherein a second electrode is provided at a position where the portion of the passivation is etched off.

13: The method for manufacturing the array structure of claim 6, wherein the first electrode is made of metal material and the second electrode is made of transparent electrode material.

14: An array substrate comprising a substrate and the array structure of claim 1, which is formed on the substrate.

15. (canceled)
